(19) United States
(12) Patent Application Publication
(10) Pub. No.: US 2025/0015044 A1
(43) Pub. Date: Jan. 9, 2025

(54) DIE-SUBSTRATE INTERFACE INCLUDING LOCKING FEATURES

(71) Applicant: SEMICONDUCTOR COMPONENTS INDUSTRIES, LLC, Scottsdale, AZ (US)

(72) Inventors: Hao YAN, Suzhou (CN); Kun FENG, Shanghai (CN); Sixin JI, NanTong (CN); ZhengDong GE, Suzhou (CN)

(73) Assignee: SEMICONDUCTOR COMPONENTS INDUSTRIES, LLC, Scottsdale, AZ (US)

(21) Appl. No.: 18/346,976

(22) Filed: Jul. 5, 2023

(51) Int. Cl. H01L 23/00; H01L 23/373

(52) U.S. Cl. CPC H01L 24/83; H01L 23/3735; H01L 24/26; H01L 24/29; H01L 24/32; H01L 2224/26152; H01L 2224/29199; H01L 2224/29339; H01L 2224/32225; H01L 2224/83385; H01L 2224/83439; H01L 2224/8384

(57) ABSTRACT

A die-attach process that creates a bond strength sufficient to hold a die to a substrate while it is handled before being permanently attached is disclosed. The die-attach process includes forming locking features in a metal layer of a substrate so a bond at the die-substrate interface is strengthened. The locking features may include a plurality of cavities or slots formed in a metal layer of the substrate. The cavities and slots can increase a surface area and provide anchor points for a die-attach film placed between the die and the substrate.

### FIELD OF THE DISCLOSURE

The present disclosure relates to electronic packaging and more specifically to a method for attaching a die to a substrate.

### BACKGROUND

A package for power electronics (e.g., power modules, solar inverters, motor controllers, etc.) may include a die to be attached to a substrate. The substrate may be implemented using direct bond copper (DBC) or active metal brazed (AMB) substrates because of their excellent thermal conductivity and electrical insulation. Dies may be attached to these substrates using a sintering process, which can help the thermal conduction. Careful alignment of a die on the substrate may be required before and after the sintering process.

### SUMMARY

Attaching a die to a substrate may include assembling a stack-up of a die and a substrate. The stack-up may then be transported to a machine where heat and pressure can be used to finalize the attachment of the die to the substrate. The stack-up may be temporarily attached (i.e., tacked) in place prior to transportation in order to prevent any shock and/or vibration from damaging or destroying the stack-up while it is in route. The present disclosure describes a means for strengthening a tacked attachment so that it is better able to withstand the shock/vibration associated with the transportation.

In some aspects, the techniques described herein relate to a method for sintering a die to a substrate, the method including: forming a plurality of locking features in a metal layer of the substrate; laminating a die-transfer film to the die; placing the die and the die-transfer film on the substrate to form a stack-up including the die-transfer film directly between the metal layer and the die; adhering the stack-up to form a tacked-stack-up; and sintering the tacked-stack-up so that the die is bonded to the substrate.

In some aspects, the techniques described herein relate to a power module including: a substrate including a plurality of locking features in a metal layer of the substrate; and a die including circuitry for the power module, the die attached to the substrate using a die-attach process including: laminating a die-transfer film to the die; placing the die and the die-transfer film on the substrate to form a stack-up including the die-transfer film directly between the metal layer and the die; adhering the stack-up to form a tacked-stack-up; and sintering the tacked-stack-up so that the die is bonded to the substrate.

In some aspects, the techniques described herein relate to a method for tacking a die to a substrate, the method including: forming a plurality of locking features in a metal layer of the substrate; laminating a die-transfer film to the die; placing the die and the die-transfer film on the substrate to form a stack-up including the die-transfer film directly between the metal layer and the die; applying a force to the die so that the stack-up is pressed together for a hot-tack period; and heating the substrate so that a temperature of the stack-up is raised during the hot-tack period, the die tacked to the substrate to form a tacked-stack-up at a conclusion of the hot-tack period.

In a possible implementation of the method for tacking the die to the substrate, the tacked-stack-up is transported and the plurality of locking features result in a bond strength of the tacked-stack-up that is sufficient to hold the tacked-stack-up together during the transportation.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIG. 1 is a perspective view of stack up for an electronic package according to a possible implementation of the present disclosure.

FIG. 2A is a top-view of the stack-up, shown in FIG. 1, with an aligned die according to a possible implementation of the present disclosure.

FIG. 2B is a top-view of the stack-up shown in FIG. 1 a misaligned die according to a possible implementation of the present disclosure.

FIG. 2C is a top-view of the stack-up shown in FIG. 1 a missing die according to a possible implementation of the present disclosure.

FIG. 3 is a side, cross-sectional view of a stack-up during a process for adhering the die to the substrate according to a possible implementation of the present disclosure.

FIG. 4 is a side cross-sectional view of die-substrate interface including a locking feature according to a possible implementation of the present disclosure.

FIG. 5 is a perspective view of a substrate having a plurality of locking features in a metal layer according to a first possible implementation of the present disclosure.

FIG. 6 illustrates a top view of a portion of the bond area shown of FIG. 5 including an inset illustrating a side-view of a representative cavity according to an implementation of the present disclosure.

FIG. 7 is a perspective view of a substrate having a plurality of locking features in a metal layer according to a second possible implementation of the present disclosure.

FIG. 8 illustrates a top view of a portion of the bond area shown in FIG. 7 including an inset illustrating a side-view of a representative slot according to an implementation of the present disclosure.

FIG. 9 is a flowchart of a method for sintering a die to a substrate according to an implementation of the present disclosure.

The components in the drawings are not necessarily to scale relative to each other. Like reference numerals designate corresponding parts throughout the several views.

### DETAILED DESCRIPTION

An electronic part (e.g., power module) may include a die connected to a substrate using a sintering process. While various materials may be used, the electronics industry may be moving to materials having a lower cost (e.g., than gold (Au)) and a lower environmental impact (e.g., than lead (Pb)). For example, silver (Ag), in a paste or a film, can be applied between a plated surface of a die and a metal layer of a substrate to form a stack-up. The stack-up can be loosely adhered (i.e., tacked) in place to prepare it for a final attachment via sintering. After the sintering, subsequent soldering processes may take place to connect the sintered-stack-up in an electronic package. Proper alignment of the die may be required for these subsequent soldering processes.

One technical problem with the tacking approach described above, is that the tacked-stack-up may be held together too loosely to withstand handling. For example, transporting the tacked-stack-up before it is sintered may create a shock/vibration that can dislodge the die. As a result, the die can become lost or misaligned, resulting in a failure of the electronic part. It may be desirable to reduce a number of failures when the cost of the electronic part is high, such as is typically the case for power modules.

A power module may use a die fabricated using a silicon carbide (SiC) material/process in order to handle the high temperatures and high voltages associated with its operation. The SiC may be more costly than other technologies (e.g., Si). Accordingly, to minimize failures of these electronic parts, the present disclosure describes systems and methods for strengthening the tacked-stack-up so that it can withstand forces during transportation without becoming dislodged. The strengthened tacked-attachment may have the technical effect of improving a production yield of the power module.

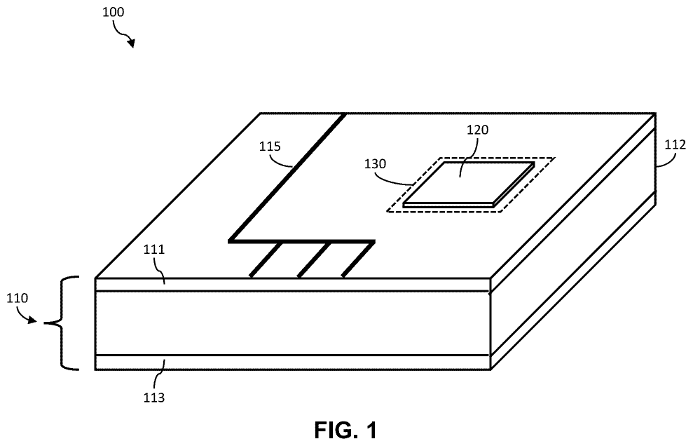

FIG. 1 is a perspective view of a stack up for a power module according to a possible implementation of the present disclosure. The stack-up may be for a power module configured for high-voltages (e.g., >10V) and high-temperatures (e.g., >100° C.) and thus may require materials suitable for this operation (e.g., ceramic, SiC, etc.).

The stack-up 100 may include a substrate 110 having a metal layer (i.e., top metal layer 111) mechanically coupled to a first surface (i.e., top surface) of an insulating layer 112. The insulating layer 112 may be a ceramic (e.g., alumina, aluminum nitride, silicon nitride) based on its electrical insulating and heat spreading characteristics. In some implementations, the substrate 110 further includes a second metal layer (i.e., bottom metal layer 113) mechanically coupled to a second surface (i.e., bottom surface) of the insulating layer 112.

The metal layer(s) can be attached to the insulating layer 112 using bonding or brazing. A bonding process used to attach the metal layer(s) results in a direct bonded metal (DBM) substrate (e.g., direct bonded copper (DBC) substrate), while a brazing process used to attach the metal layer(s) results in an active metal brazed (AMB) substrate.

The top metal layer 111 and the bottom metal layer 113 may be copper (Cu), which can be plated to aid in die attachment. For example, a copper metal layer may be silver plated to match a silver based die attach paste (DAP) or a silver based die-transfer film (DTF). The top metal layer 111 and/or the bottom metal layer 113 of the substrate 110 may be etched, or otherwise divided, to form traces 115 to interconnect circuitry to other devices/components. For example, the metal layer may be etched to form a pad that can be wire-bonded to a lead frame of a chip package (not shown).

As shown, a die 120 may be placed in a bond area 130 on the top metal layer 111 of the substrate 110 to form a stack-up 100. In a possible implementation, the die 120 can include an integrated circuit (IC) for a power module, such as an insulated gate bipolar transistor (IGBT) or a power metal oxide semiconductor field effect transistor (power MOSFET). While the ceramic substrate material and SiC die material are described in detail because of their suitability for power modules, it should be noted that the disclosed techniques may be used with other materials and for other electronic parts. For example, a die may be another material, such as silicon (Si), gallium arsenide (GaAs), or glass.

In order for the die 120 to make proper contact with traces and/or wires, proper alignment of the die within the bond area 130 may be required. Automation may be used to pick and place the die 120 accurately in the bond area 130. In some cases, however, a die may become misaligned within the bond area 130 or may become detached from the top metal layer 111 altogether.

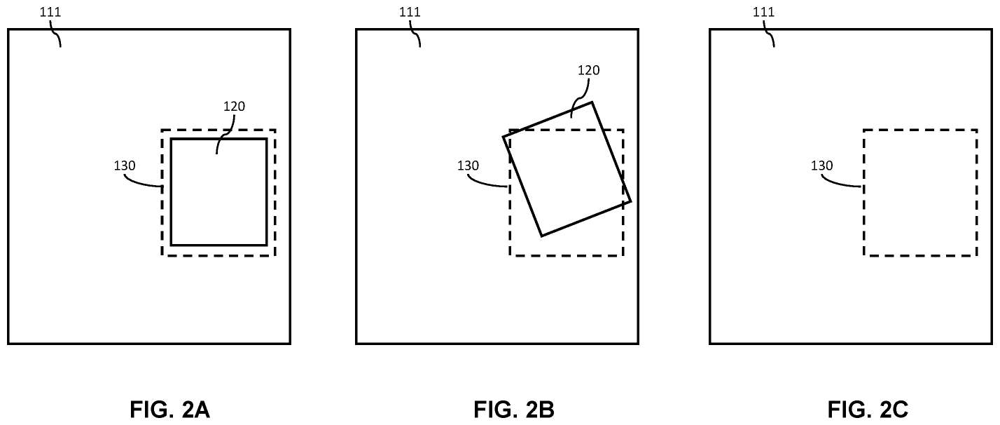

FIG. 2A is a top-view of the stack-up 100, as shown in FIG. 1, with a die aligned with the bond area 130 (i.e., an aligned die). An aligned die may be characterized as having edges (i.e., sides) aligned with (i.e., parallel with, flush with) edges (i.e., sides) of the bond area 130. FIG. 2B is a top-view of the stack-up shown in FIG. 1 with a die misaligned with the bond area 130 (i.e., a misaligned die). A misaligned die may be characterized as having edges (i.e., sides) not aligned with (i.e., not parallel with, not flush with) edges (i.e., sides) of the bond area 130. FIG. 2C is a top-view of the stack-up shown in FIG. 1 with a die missing from the bond area 130 (i.e., a missing die). The die may be missing as a result of becoming detached and falling off of the substrate 110.

A misaligned die and/or a missing die may result from a shock and/or vibration. The shock/vibration may be associated with a movement of the stack-up 100. For example, the movement may result from transporting the stack-up 100 between machines in a production environment. For example, the stack-up 100 may be transported from a pick-and-place machine, configured to place the die 120 on the substrate 110, to a sintering machine configured to permanently attach the die 120 to the substrate 110.

A misaligned die or a missing die may result in a failure of a part in a production environment. For example, a misaligned die that is permanently attached by sintering may not make proper connection with pads, traces, and/or wires of the substrate. Accordingly, to avoid misaligned or missing die conditions, the die can be temporarily attached (i.e., adhered, tacked) in place (i.e., in the bond area 130) to allow handling (e.g., movement, transportation) before it is permanently attached. Adhering the die 120 for transport may be carried out using a hot-tack process.

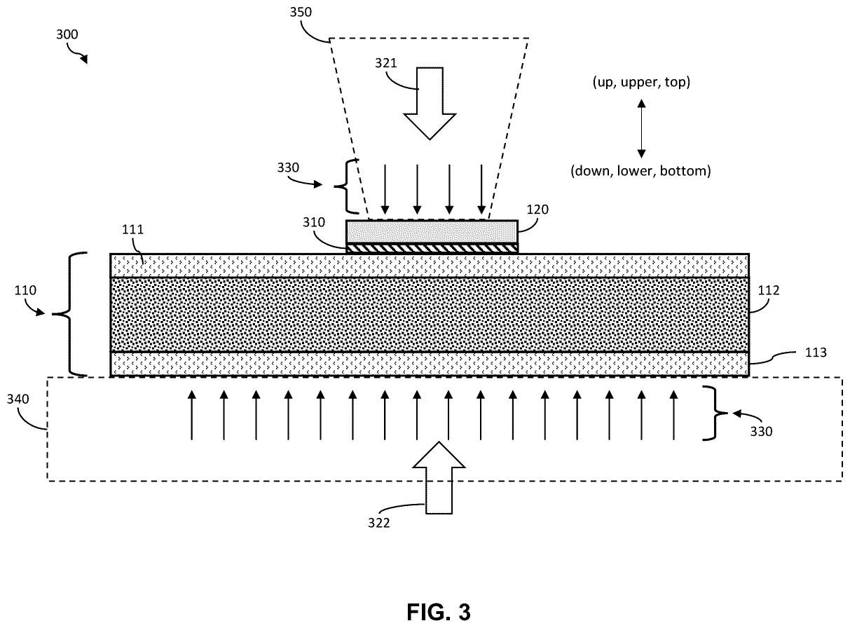

FIG. 3 is a side cross-sectional view of a stack-up during a process for adhering the die to the substrate according to a possible implementation of the present disclosure. The process for adhering (i.e., tacking) the die to the substrate (i.e., hot-tack process) can include forming a stack-up 300 as shown. The stack-up 300 can include a die-transfer film 310 (DTF) positioned between (e.g., directly between) a die 120 and a metal layer (e.g., top metal layer 111) of the substrate 110.

The die-transfer film 310 may have a size and shape that approximately (e.g., <1% difference) matches the size and shape of the die 120. In a possible implementation, the die-transfer film is laminated to a surface (e.g., bottom surface) of the die 120 prior to forming (i.e., assembling) the stack-up. The lamination process may include cutting the die-transfer film 310 to fit the die 120. The die-transfer film 310 may include metal nanoparticles in a matrix. For example, the die-transfer film 310 may include silver (Ag) nanoparticles in an adhesive matrix. In this case, the top metal layer 111 may be silver plated to help the sintering process.

The process for tacking the die 120 to the top metal layer 111 may further include applying heat 330 to the stack-up 300. In a possible implementation, applying the heat 330 may include positioning a first heat source at the bottom metal layer 113. For example, the stack-up 300 may be placed on a base plate 340, which can be heated to a first temperature in order to indirectly heat the die-transfer film 310 from a first direction. In a possible implementation, applying heat 330 to the stack-up 300 may further include positioning a second heat source at a top-surface of the 120 die. For example, a head 350 used to pick-and-place the die 120 may be heated to a second temperature in order to heat the die-transfer film 310 from a second direction. The first temperature and the second temperature can be controlled in order to raise a temperature of the die-transfer film 310 to a hot-tack temperature and hold the temperature at the hot-tack temperature for a hot-tack period before allowing the die-transfer film 310 to cool.

In a possible implementation, the process for tacking the die 120 to the top metal layer 111 may further include applying pressure to the stack-up 300. In a possible implementation, applying the pressure may include pressing (e.g., moving) the head 350 downward on the die 120 so that a first force 321 is applied downward on a top surface of the die 120. The base plate 340 may be fixed (or pressed) so that a second force 322 is applied upward on the bottom metal layer 113. The net result of the first force and second force is a squeezing of the die-transfer film 310 between the die 120 and the top metal layer 111. For example, the stack-up can be pressed together by lowering the head 350 onto the die 120 while the stack-up rests on the base plate 340. The first force 321 and the second force 322 may be applied during the hot-tack period.

The temperature and pressure can be raised during the hot-tack period and lowered after the hot-tack period. For example, at the end of the hot-tack period the pressure on the stack-up is released and the stack-up is allowed to cool. After cooling the die 120 may be adhered (i.e., bonded) to the top metal layer 111 by the die-transfer film 310. A strength of the bond (i.e., bond strength) of this adhesive connection corresponds to an amount of force necessary to break the adhesive connection. In other words, the bond strength can hold the stack-up intact when the forces applied to the stack-up are smaller than the bond strength. Because the heat/pressure applied during a hot-tack process may be less than a heat/pressure applied during a sintering process so the bond strength resulting from a hot-tack process is not as high as a bond strength resulting from sintering process. The bond strength can be made stronger (i.e., increased) through the use of locking features formed in the metal layer of the substrate.

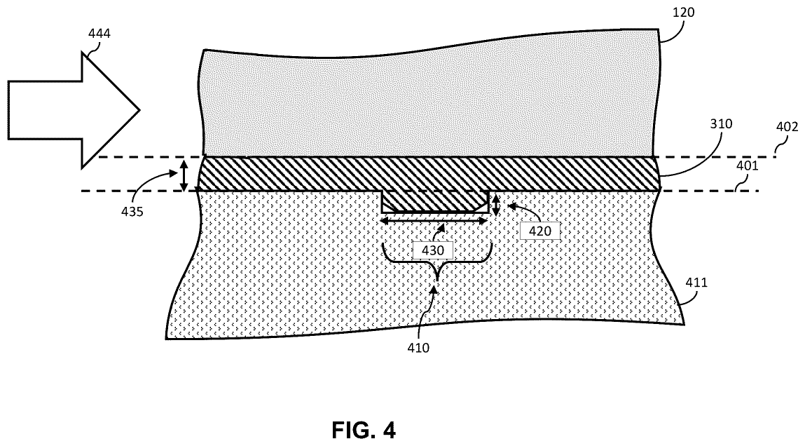

FIG. 4 is a side cross-sectional view of die-substrate interface including a locking feature according to a possible implementation of the present disclosure. As shown, the locking feature 410 is included in a metal layer 411 of the substrate and breaks a plane 401 defined by a surface of the metal layer 411. Accordingly, the locking feature 410 can make the surface of the metal layer 411 nonplanar and can increase the surface area of the metal layer 411. The locking feature 410 can have virtually any size and shape as long as it breaks a plane 401 (i.e., surface) of the metal layer. For example, the locking feature 410 can define a bulge in the surface of the metal layer 411 that rises above the plane 401 or can define a depression in the surface of the metal layer 411 that drops below the plane 401 Accordingly, a die-substrate interface including a locking feature can resist a force 444 in a direction that is parallel with the plane 401 better than a die-substrate interface without a locking feature.

The locking feature 410 illustrated in FIG. 4 is a cross-section of a slot (i.e., groove, notch, etc.) or cavity (i.e., pit, concavity, pocket, dimple) formed in a top surface of the metal layer 411. The locking feature 410 has a volume corresponding to an amount of the metal layer 411 removed in order to form the locking feature. The volume is defined by depth 420 of the locking feature 410 from a surface of the metal layer 411 (i.e., plane 401). In a possible implementation, the depth 420 of the locking feature is in a range of 10 to 20 micrometers (i.e., microns). The volume is further defined by a width 430, which can be in a range of 10 to 20 microns.

The hot-tack process described above may soften and compress the die-transfer film 310 during the hot-tack period. According, after cooling the 310 may partially fill, or completely fill, the volume of the locking feature 410. The increased bond area and grip (i.e., anchor) provided by the locking feature 410. The depth 420 of the locking feature 410 and a thickness 435 of the die-transfer film 310 may be selected so that during and after a hot-tack process, the die-transfer film 310 fills the locking feature 410 while providing a planar surface 402 for the die 120. In other words, the die transfer film may have a thickness 435 that is greater than the depth 420 so that (in the stack-up) the die-transfer film 310 conforms to the locking feature at a first side (facing the metal layer 411) and does not conform to the locking feature on a second side (facing the die 120). The planar surface 402 of the die-transfer film 310 on the side facing the die 120 may be helpful in preventing cracks in the die 120. The locking feature shown in FIG. 4 may be one locking feature of a plurality of similar (i.e., the same) locking features on a surface of the substrate.

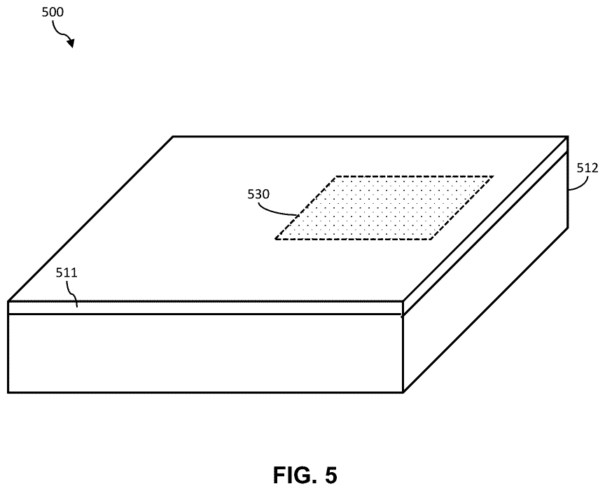

FIG. 5 is a perspective view of a substrate 500 having a plurality of locking features in a metal layer 511 according to a first possible implementation of the present disclosure. The locking features are a plurality of cavities. In a possible implementation, the plurality of cavities are designed to have the same size and shape. The plurality of cavities are arranged on the metal layer 511 in a pattern. In a possible implementation the pattern of cavities is random. In a possible implementation, the pattern of cavities is not symmetric in two dimensions. In a possible implementation, the pattern of cavities repeats in two dimensions with the same spatial frequency in each dimension. In a possible implementation, the pattern of cavities repeats in two dimensions with different spatial frequencies in each dimension. In a possible implementation the pattern of cavities repeats in one dimension. In a possible implementation, the pattern of cavities covers an entire portion of the metal layer 511. In a possible implementation, the pattern of cavities covers a portion of the metal layer 511. For example, as shown in FIG. 5, the pattern of cavities repeats in two dimensions (with the same spatial frequency) and covers a bond area 530 of a metal layer 511 of a substrate 500, where the metal layer 511 is coupled to an insulating layer 512. In other words, the cavities can be in the bond area 530 of the metal layer 511 but not in other areas of the metal layer 511.

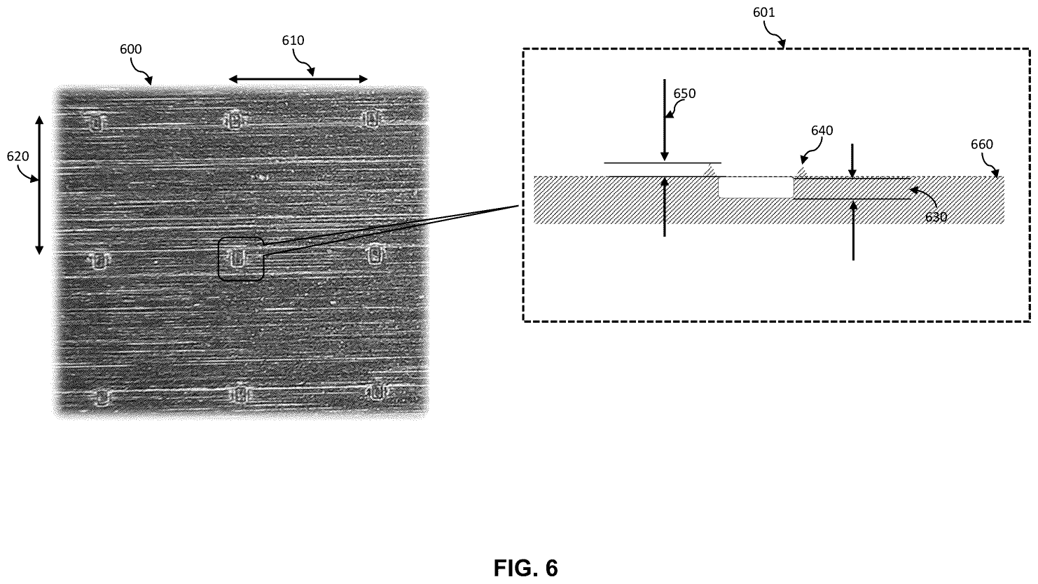

FIG. 6 illustrates a top view 600 of a portion of the bond area 530 shown in FIG. 5 and includes an inset 601 illustrating a side-view of a representative cavity according to an implementation of the present disclosure. As shown in the top view 600 the cavities are formed to have a repeating pattern with a first spatial period 610 in a first direction and a second spatial period 620 in a second direction, which are the same. In a possible implementation, forming the plurality of locking features include stamping the metal layer to form the cavities. In another possible implementation, forming the plurality of locking features includes laser etching the metal layer to form the cavities.

As shown in the inset 601, each cavity of the plurality of cavities may have a depth 630 that is in a range of 10 to 20 microns. The process of forming the cavity can create an edge 640 that is raised above a surface of the metal layer by a height 650. This height 650 may be made less than 10 microns to prevent cracking a die as it is pressed onto the surface 660 of the metal layer during a hot-tack process or a sintering process.

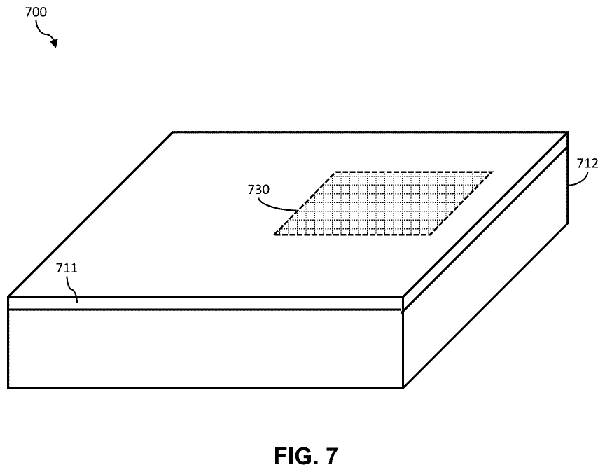

FIG. 7 is a perspective view of a substrate 700 having a plurality of locking features in a metal layer 711 on a substrate, where the metal layer 711 is coupled to an insulating layer 712. The locking features are a plurality of slots. The slots include a plurality of slots in a first direction and a plurality of slots in a second direction. In a possible implementation, an angle between the first direction and the second direction is in a range from 45 degrees to 90 degrees. For example, the angle between the first direction and the second direction may be 90 degrees. In a possible implementation the slots in the first direction are a first size and the slots in the second direction are second size. The sizes may be the same. For example, each slot may have a width that is in a first range of 10 to 20 microns and a depth that is in a range of 10 to 20 microns.

The plurality of slots in the first direction and the plurality of slots in the second direction form a crosshatch pattern that covers a portion (e.g., an entire portion) of the metal layer 711. As shown, the crosshatch pattern is formed in a bond area 730 of the metal layer 711 but is absent in areas other than the bond area 730. The cross hatch pattern may have a first period in the first direction and a second period in a second direction. In a possible implementation, the first period is equal to the second period. For example, the first period in the first direction can be approximately 1000 microns (±50 microns) and the second period in the second direction can be approximately 1000 microns (±50 microns).

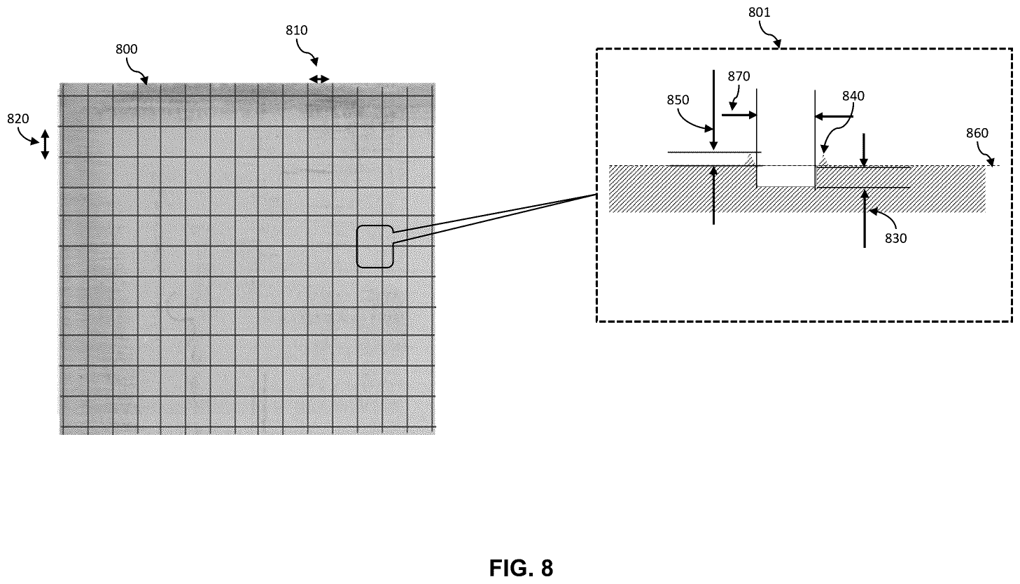

FIG. 8 illustrates a top view 800 of a portion of the bond area 730 shown of FIG. 7 and includes an inset 801 illustrating a side-view of a representative slot according to an implementation of the present disclosure. As shown in the top view 800 the cavities are formed to have a repeating pattern with a first period 810 in a first direction and a second period 820 in a second direction. As shown, the second period 820 can be larger than the first period 810. In a possible implementation, forming the plurality of locking features include stamping the metal layer to form the slots. In another possible implementation, forming the plurality of locking features includes laser etching the metal layer to form the slots.

As shown in the inset 801, each slot of the plurality of slots may have a depth 830 that is in a range of 10 to 20 microns and a width 870 that is in a range of 10 to 20 microns. The process of forming the slot can create an edge 840 that is raised above a surface of the metal layer by a height 850. This height 850 may be made less than 10 microns to prevent cracking a die as it is pressed onto the surface 860 of the metal layer during a hot-tack or sintering process.

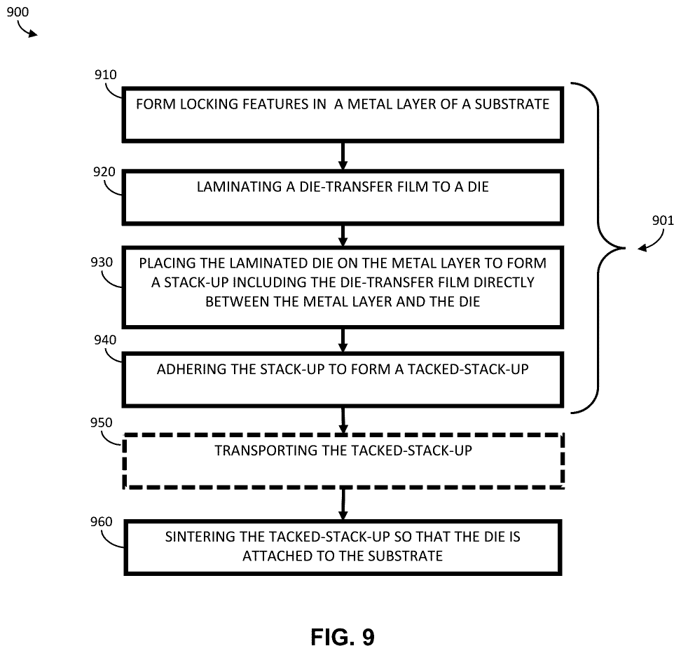

FIG. 9 is a flow chart of a method for attaching a die to a substrate (i.e., die-attach process 900) according to a possible implementation of the present disclosure. The die attach process 900 may include a method for tacking a die to a substrate (i.e., hot-tack process 901), which may be part of a method for sintering a die to a substrate.

The die-attach process 900 includes forming 910 a plurality of locking features (e.g., cavities, slots) in a metal layer (e.g., silver plated copper layer) of a substrate (e.g., DBC substrate). Forming 910 (i.e., fabricating) of the plurality of locking features may be carried out using a variety of technologies. Possible technologies for forming locking features may include (but not limited to) chemical etching, machining (e.g., punching, stamping, milling), laser etching, coating, molding, and plasma etching. Any combination of these technologies may also be used to form the locking features in the metal layer.

The die-attach process 900 may further include laminating 920 a die-transfer film (e.g., Ag nanoparticle film) to a die (e.g., SiC die). The die-attach process 900 may further include placing 930 the laminated die on the metal layer to form a stack-up including the die-transfer film directly between the metal layer and the die. The die-attach process 900 may further include adhering 940 the stack-up (e.g., applying heat and pressure to the stack-up for a hot-tack period) to form a tacked-stack-up. The die-attach process 900 may further including moving (i.e., transporting 950) the tacked-stack-up (e.g., between stations in a facility) and sintering 960 the tacked-stack-up so that the die is attached to the substrate.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

1. A method for sintering a die to a substrate, the method comprising:
forming a plurality of locking features in a metal layer of the substrate;
laminating a die-transfer film to the die;
placing the die and the die-transfer film on the substrate to form a stack-up including the die-transfer film directly between the metal layer and the die;
adhering the stack-up to form a tacked-stack-up; and
sintering the tacked-stack-up so that the die is bonded to the substrate.

2. The method according to claim 1, wherein the plurality of locking features make a bond strength of the tacked-stack-up is stronger than without the plurality of locking features.

3. The method according to claim 2, further comprising:
transporting the tacked-stack-up before sintering, wherein the transportation causes a force on the tacked-stack-up, the bond strength being stronger than the force.

4. The method according to claim 1, wherein:
the substrate is a direct bonded copper (DBC) substrate including a ceramic layer in between a first copper layer and a second copper layer; and
the metal layer is the first copper layer.

5. The method according to claim 1, wherein:
the substrate is an active matrix brazing (AMB) substrate including a ceramic layer in between a first copper layer and a second copper layer; and
the metal layer is the first copper layer.

6. The method according to claim 1, wherein:
the metal layer is silver plated; and
the die-transfer film includes silver nanoparticles in an adhesive matrix.

7. The method according to claim 1, wherein forming the plurality of locking features in the metal layer includes:
stamping the metal layer to form the plurality of locking features.

8. The method according to claim 1, wherein forming the plurality of locking features in the metal layer includes:
laser etching the metal layer to form the plurality of locking features.

9. The method according to claim 1, wherein the plurality of locking features are arranged on the metal layer of the substrate in a repeating pattern.

10. The method according to claim 1, wherein the plurality of locking features includes a plurality of cavities in the metal layer.

11. The method according to claim 10, wherein each cavity of the plurality of cavities has a depth in a range of 10 to 20 microns.

12. The method according to claim 10, wherein each cavity of the plurality of cavities has an edge that is raised above a surface of the metal layer by a height that is less than 10 microns.

13. The method according to claim 1, wherein the plurality of locking features includes a plurality of slots in a first direction and in a second direction, the first direction at an angle with the second direction so that the plurality of slots form a crosshatch pattern over the metal layer of the substrate.

14. The method according to claim 13, wherein the crosshatch pattern has a first period in the first direction of approximately 1000 microns and a second period in the second direction of approximately 1000 microns.

15. The method according to claim 13, wherein each slot of the plurality of slots includes has a width in a first range of 10 to 20 microns and a depth in a second range of 10 to 20 microns.

16. The method according to claim 13, wherein each slot of the plurality of slots has an edge that is raised above a surface the metal layer by a height that is less than 10 microns to prevent cracking the die during the sintering.

17. A power module comprising:
a substrate including a plurality of locking features in a metal layer of the substrate; and
a die including circuitry for the power module, the die attached to the substrate using a die-attach process including:
laminating a die-transfer film to the die;
placing the die and the die-transfer film on the substrate to form a stack-up including the die-transfer film directly between the metal layer and the die;
adhering the stack-up to form a tacked-stack-up; and
sintering the tacked-stack-up so that the die is bonded to the substrate.

18. The power module according to claim 17, wherein the die is silicon carbide (SiC) and the substrate is a direct bonded copper (DBC) substrate.

19. The power module according to claim 17, wherein the metal layer is silver plated copper and the die-transfer film includes silver nanoparticles in an adhesive matrix.

20. The power module according to claim 17, wherein the plurality of locking features are a plurality of cavities in the metal layer that are arranged in a repeating patter over the metal layer of the substrate.

21. The power module according to claim 17, wherein the plurality of locking features are slots in the metal layer, the slots arranged in a first direction and in a second direction, the first direction at an angle with the second direction so that the slots form a crosshatch pattern over the metal layer of the substrate.

22. The power module according to claim 17, wherein the die-transfer film has a thickness and the plurality of locking features have a depth, the thickness greater than the depth so that, in the stack-up, the die-transfer film conforms to the plurality of locking features on a first side facing the metal layer and does not conform to the plurality of locking features on a second side facing the die.

23. A method for tacking a die to a substrate, the method comprising:
forming a plurality of locking features in a metal layer of the substrate;
laminating a die-transfer film to the die;
placing the die and the die-transfer film on the substrate to form a stack-up including the die-transfer film directly between the metal layer and the die;
applying a force to the die so that the stack-up is pressed together for a hot-tack period; and
heating the substrate so that a temperature of the stack-up is raised during the hot-tack period, the die tacked to the substrate to form a tacked-stack-up at a conclusion of the hot-tack period.

24. The method for tacking the die to substrate according to claim 23, further comprising:
transporting the tacked-stack-up, wherein the plurality of locking features result in a bond strength of the tacked-stack-up that is sufficient to hold the stack-up in tact while transporting the die tacked to the substrate.
